(19) United States
(12) Patent Application Publication
(10) Pub. No.: US 2016/0034094 A1
(43) Pub. Date: Feb. 4, 2016

(54) PROGRAMMABLE GAIN AMPLIFIERS WITH OFFSET COMPENSATION AND TOUCH SENSOR CONTROLLER INCORPORATING THE SAME

(71) Applicant: Samsung Electronics Co., Ltd., Suwon-si (KR)

(72) Inventors: Sang-Hyub Kang, Hwasung-Si (KR); Ki-Duk Kim, Hwasung-Si (KR); Jun-Chul Park, Daegu (KR); Ho-Jin Park, Suwon-Si (KR); Kyung-Hoon Lee, Seoul (KR); Min-Chul Lee, Yongin-si (KR); Jin-Chul Lee, Seoul (KR); Choong-Hoon Lee, Seoul (KR); Michael Choi, Hwasung-si (KR); Yoon-Kyung Choi, Seoul (KR)

(21) Appl. No.: 14/807,530

(22) Filed: Jul. 23, 2015

(30) Foreign Application Priority Data
Jul. 30, 2014 (KR) 10-2014-0097587

(51) Int. Cl. G06F 3/041; H03F 3/45; H03G 3/00

(52) U.S. Cl. CPC G06F 3/0416; H03G 3/00; H03F 3/45076; H03F 2200/129; H03F 2200/228; H03F 2203/45116

(57) ABSTRACT

A programmable gain amplifier (PGA) circuit includes a first input resistor coupled between a first input node and a first summing node and a second input resistor coupled between a second input node and a second summing node. The PGA circuit further includes a first variable reference resistor coupled between a third input node and the first summing node, a second variable reference resistor coupled between a fourth input node and the second summing node, and an operational amplifier having first and second inputs coupled to respective ones of the first and second summing nodes and first and second outputs coupled to respective ones of the first and second output nodes. At least of the first and second reference resistors may include an R-2R ladder circuit.

### CROSS-REFERENCE TO RELATED APPLICATION

This application claims priority under 35 U.S.C. §119 to Korean Patent Application No. 10-2014-0097587 filed on Jul. 30, 2014, the entire contents of which are incorporated herein by reference in their entirety.

### BACKGROUND

Embodiments of the inventive subject matter relate to touch sensor apparatus and, more particularly, to programmable gain amplifier (PGA) circuits and touch sensor controllers incorporating the same.

When making a call with a cellular phone, a user may input the number by pressing a keypad. However, it may be is difficult to press a keypad button in order to make a call. Some peripheral devices, such as cellular phones, tablets and personal computers (PCs) use touch screens to receive user inputs. Touch screens are also used in medical devices, vehicles, home appliances, etc.

Touch screens may be classified as pressure sensitive type that uses a resistor that reacts to a pressure on a surface of a screen or a capacitive type that uses a capacitor that discharges an amount of charge when the surface of the screen is touched. Capacitive type touch screens are now widely used and may provide high resolution and sensitivity.

### SUMMARY

Some embodiments of the inventive subject matter can provide a programmable gain amplifier (PGA) circuit which can be implemented with a small size. Further embodiments of the inventive subject matter can provide a touch sensor controller having the PGA circuit.

Some embodiments provide a programmable gain amplifier (PGA) circuit including a first input resistor coupled between a first input node and a first summing node, a second input resistor coupled between a second input node and a second summing node, a first feedback resistor coupled between the first summing node and a first output node, and a second feedback resistor coupled between the second summing node and a second output node. The PGA circuit further includes a first reference resistor coupled between a third input node and the first summing node, a second reference resistor coupled between a fourth input node and the second summing node, and an operational amplifier having first and second inputs coupled to respective ones of the first and second summing nodes and first and second outputs coupled to respective ones of the first and second output nodes, wherein at least one of the first and second reference resistors includes a R-2R ladder circuit, which may be used to provide a variable resistance.

In some embodiments, the first and second input resistors may have the same resistance value. In some embodiments, the first and second feedback resistors may have the same resistance value and the first and second feedback resistors may include variable resistors. The PGA circuit may further include a first switch configured to selectively couple the third input node to positive and negative voltage reference nodes and a second switch configured to selectively couple the fourth input node to the positive and negative reference voltage nodes.

Further embodiments provide a PGA circuit including a first input resistor coupled between a first input node and a first summing node, a second input resistor coupled between a second input node and a second summing node, a first feedback resistor coupled between the first summing node and a first output node, and a second feedback resistor coupled between the second summing node and a second output node. The PGA circuit further includes a first variable reference resistor coupled between a third input node and the first summing node, a second variable reference resistor coupled between a fourth input node and the second summing node, and an operational amplifier having an input coupled to the first and second summing nodes and an output coupled to the first and second output nodes.

In some embodiments, at least one of the first and second reference resistors may include an R-2R ladder circuit. The R-2R ladder circuit may include a plurality of switches operative to vary a resistance of the R-2R ladder circuit responsive to control signals applied to the switches.

In some embodiments, the PGA circuit may further include a first switch configured to selectively couple the third input node to positive and negative voltage reference nodes and a second switch configured to selectively couple the fourth input node to the positive and negative reference voltage nodes.

Further embodiments provide a touch sensor controller including a demodulator configured to be coupled to a touch sensor and to generate a DC output voltage responsive to an input to the touch sensor and a programmable gain amplifier (PGA) circuit including first and second input nodes coupled to an output of the demodulator. The PGA circuit further includes a first input resistor coupled between the first input node and a first summing node, a second input resistor coupled between the second input node and a second summing node, a first feedback resistor coupled between the first summing node and a first output node, a second feedback resistor coupled between the second summing node and a second output node, a first variable reference resistor coupled between a third input node and the first summing node, a second variable reference resistor coupled between a fourth input node and the second summing node, and an operational amplifier having an input coupled to the first and second summing nodes and an output coupled to the first and second output nodes. The touch sensor controller further includes an analog-to-digital converter (ADC) having an input coupled to the first and second output nodes of the PGA circuit.

In some embodiments, at least one of the first and second reference resistors may include an R-2R ladder circuit. The R-2R ladder circuit may include a plurality of switches operative to vary a resistance of the R-2R ladder circuit responsive to control signals applied to the switches. The PGA circuit may further include a first switch configured to selectively couple the third input node to positive and negative voltage reference nodes and a second switch configured to selectively couple the fourth input node to the positive and negative reference voltage nodes.

### BRIEF DESCRIPTION OF THE DRAWINGS

The foregoing and other features and advantages of the inventive subject matters will be apparent from the more particular description of preferred embodiments of the inventive subject matters, as illustrated in the accompanying drawings in which like reference characters refer to the same parts throughout the different views. The drawings are not necessarily to scale, emphasis instead being placed upon illustrating the principles of the inventive subject matters. In the drawings:

FIG. 1 is a block diagram illustrating a touch sensor controller according to some embodiments of the inventive subject matter;

FIGS. 2A and 2B are graphs illustrating an input and an output of a programmable gain amplifier (PGA) circuit shown in FIG. 1;

FIG. 3 illustrates a conventional PGA circuit;

FIG. 4 illustrates a PGA circuit according to some embodiments of the inventive subject matter;

FIG. 5 is a circuit implementation of the first or second reference resistor shown in FIG. 4 with an R-2R ladder structure;

FIG. 6 is a circuit implementation of the first or second reference resistor shown in FIG. 4 with a parallel structure;

FIG. 7 is a circuit implementation for the first or second reference resistor shown in FIG. 4 with a serial structure;

FIG. 8 illustrates a PGA circuit according to another embodiment of the inventive subject matter;

FIG. 9 is a block diagram illustrating a computer system including a touch sensor controller (TSC) shown in FIG. 1 in accordance with some embodiments of the inventive subject matter;

FIG. 10 is a block diagram illustrating a computer system including the TSC shown in FIG. 1 in accordance with another embodiment of the inventive subject matter;

FIG. 11 is a block diagram illustrating a computer system including the TSC shown in FIG. 1 in accordance with still another embodiment of the inventive subject matter;

FIG. 12 illustrates a digital camera device 400 including the TSC shown in FIG. 1;

FIGS. 13A and 13B illustrate wearable devices including the TSC shown in FIG. 1; and

FIG. 14 illustrates a wearable device including the TSC shown in FIG. 1;

### DETAILED DESCRIPTION

Example embodiments of the present invention are described below in sufficient detail to enable those of ordinary skill in the art to embody and practice the present invention. It is important to understand that the present invention may be embodied in many alternate forms and should not be construed as limited to the example embodiments set forth herein.

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention.

It will be understood that, although the terms “first,” “second,” “A,” “B,” etc. may be used herein in reference to elements of the invention, such elements should not be construed as being limited by these terms. For example, a first element could be termed a second element, and a second element could be termed a first element, without departing from the scope of the present invention. Herein, the term “and/or” includes any and all combinations of one or more referents.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

The terminology used herein to describe embodiments of the invention is not intended to limit the scope of the invention. The articles “a,” “an,” and “the” are singular in that they have a single referent, however the use of the singular form in the present document should not preclude the presence of more than one referent. In other words, elements of the invention referred to as in singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Unless otherwise defined, all terms (including technical and scientific terms) used herein are to be interpreted as is customary in the art to which this invention belongs. It will be further understood that terms in common usage should also be interpreted as is customary in the relevant art and not in an idealized or overly formal sense unless expressly so defined herein.

When it is possible to implement any embodiment in any other way, a function or an operation specified in a specific block may be performed differently from a flow specified in a flowchart. For example, consecutive two blocks may actually perform the function or the operation simultaneously, and the two blocks may perform the function or the operation conversely according to a related operation or function.

Some embodiments of the present inventive subject matter will be described below with reference to accompanying drawings.

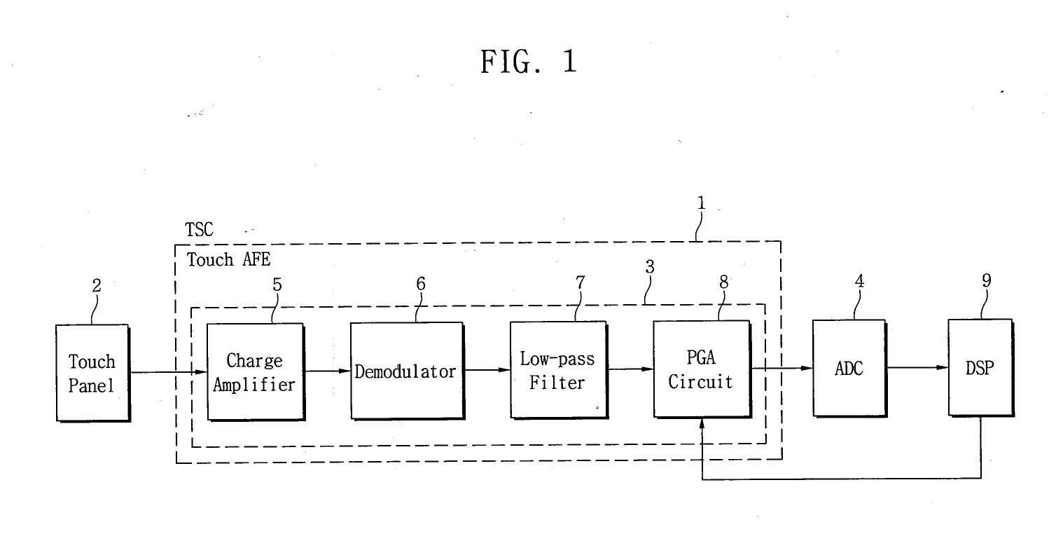

FIG. 1 is a block diagram illustrating a touch sensor controller according to some embodiments of the inventive subject matter.

Referring to FIG. 1, a touch sensor controller 1 according to some embodiments of the inventive subject matter may receive a touch signal from a touch panel 2 and generate a digital input signal. The touch sensor controller 1 may include a touch analog front-end (AFE) 3 and an analog-to-digital converter (ADC) 4.

The touch AFE 3 may receive the touch signal from the touch panel 2 and process the received touch signal. The touch AFE 3 may transmit the processed touch signal to ADC 4. The touch AFE 3 may include a charge amplifier 5, a demodulator 6, a low-pass filter 7, and a programmable gain amplifier (PGA) circuit 8.

The touch panel 2 may change an amount of capacitance responsive to a touch input. An offset may be determined by a difference between an amount of charge charged in the touch panel 2 and an amount of charge discharged by the touch signal. That is, the charge amplifier 5 may generate a constant frequency signal, and the demodulator 6 may transform the constant frequency signal to a DC signal. The low-pass filter 7 may remove high-frequency noise from the DC signal. To improve touch sensitivity, the PGA circuit 8 may amplify the DC signal. For example, the PGA circuit 8 may amplify the DC signal up to an input signal range of the ADC 9.

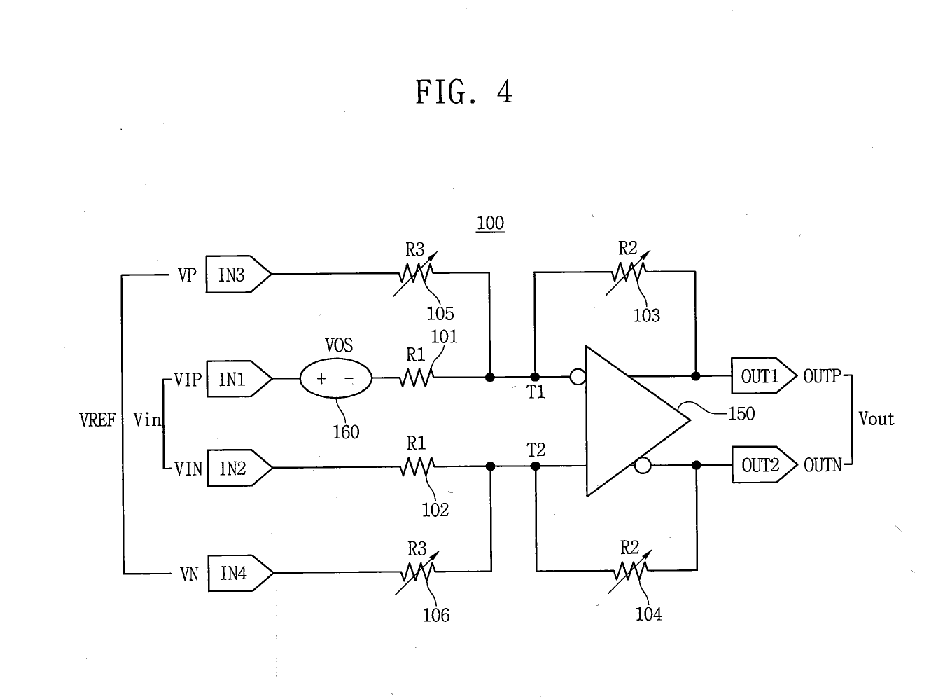

The ADC 4 may transform the signal produced by the PGA circuit 8 to a digital signal. The ADC 4 may transmit the digital signal to a digital signal processor (DSP) 9. The DSP 9 may process the digital signal. The DSP 9 may also control the PGA circuit 8 based on the digital signal. For example, the DSP 9 may control the PGA circuit 8 to remove an offset. A PGA circuit 8 according to some embodiments of the inventive subject matter will be described in FIG. 4.

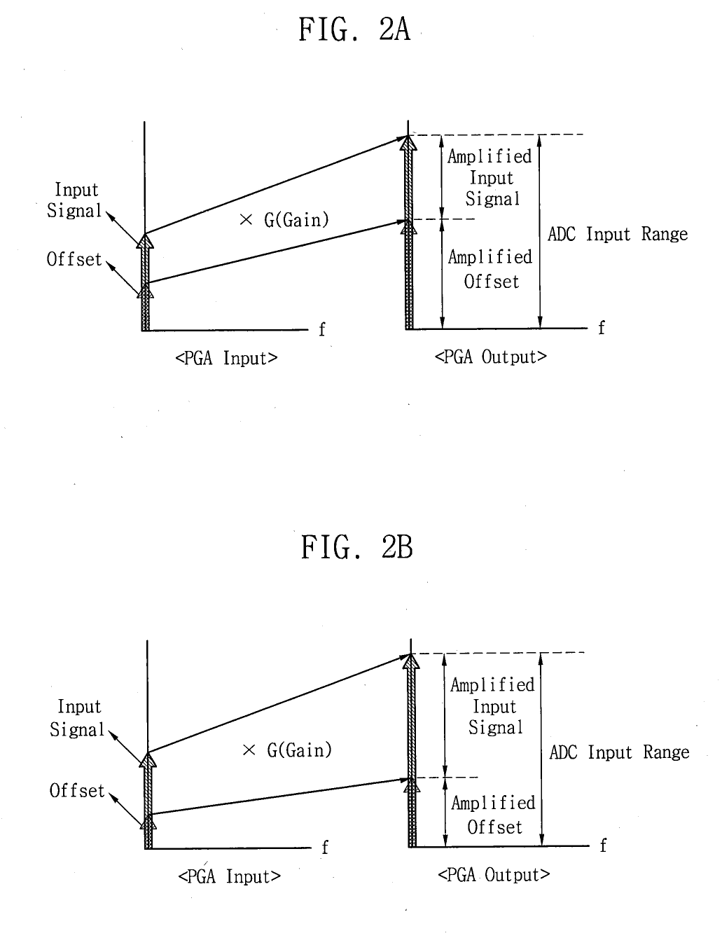

FIGS. 2A and 2B are graphs illustrating an input and an output of the PGA circuit shown in FIG. 1.

Referring to FIGS. 1 and 2A, the demodulator 6 transforms an AC touch signal to a DC signal. Here, the transformed DC signal includes an offset. When the PGA circuit 8 amplifies the DC signal, the offset is also amplified. Accordingly, the offset may limit the effective range of the amplified input signal component of the DC signal when the PGA circuit 8 increases the DC signal up to an input signal range of the ADC 9.

For example, the PGA circuit 8 may amplify the DC signal at a gain G. However, because the offset component is included in the DC signal, the PGA circuit 8 may not amplify the input signal component of the DC signal up to the input signal range of the ADC 9.

As the magnitude of the touch input signal decreases, the effect of the offset may increase. When an input signal of the PGA circuit 8 becomes smaller than the offset, the amplified offset voltage may be greater than the amplified input signal. Referring to FIGS. 1 and 2B, when the amplified input signal component of the output signal of the PGA circuit 8 is greater than the offset, the effect of the offset voltage decreases.

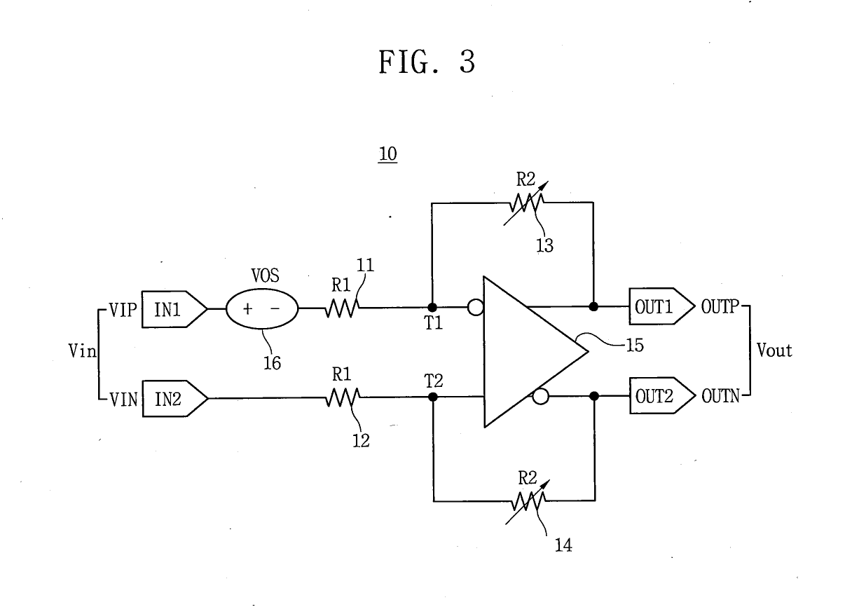

FIG. 3 is a circuit illustrating a conventional PGA circuit 10, which may not remove an offset. The conventional PGA circuit 10 includes a first input resistor 11, a second input resistor 12, a first feedback resistor 13, a second feedback resistor 14, and an operational amplifier (OP-AMP) 15. The first input resistor 11 is connected between a first input node IN1 and a first summing node T1. The second input resistor 12 is connected between a second input node IN2 and a second summing node T2. In some embodiments, the first and second input resistors 11 and 12 may have the same resistance value. A resistance value of each of the first and second input resistors 11 and 12 may be R1.

A positive input voltage VIP may include an offset 16. For example, a voltage of the offset 16 may be defined as VOS.

The positive input voltage VIP may be applied to the first input node IN1. A negative input voltage VIN may be applied to the second input node IN2. An input voltage Vin may be defined as a voltage difference between the positive input voltage VIP and the negative input voltage VIN.

The first feedback resistor 13 is connected between the first summing node T1 and a first output node OUT1. The second feedback resistor 14 is connected between the second summing node T2 and a second output node OUT2. The first and second feedback resistors 13 and 14 may have the same resistance value. The first and second feedback resistors 13 and 14 may be variable resistors. A resistance value of each of the first and second feedback resistors 13 and 14 may be R2.

An input of the OP-AMP 15 is connected to the first and second nodes N1 and N2. An output of the OP-AMP 15 is connected to the first and second output nodes OUT1 and OUT2.

When voltage of the first output node OUT1 is a positive output voltage OUTP and voltage of the second output node OUT2 is a negative output voltage OUTN, an output voltage (Vout) of the conventional PGA circuit 10 may be given by:

$$Vout = \frac{R 2}{R 1} \times Vin + \frac{R 2}{R 1} \times V O S \qquad ( Equation 1 )$$

Ideally, the output voltage Vout of the conventional PGA circuit 10 may be defined as

$$\frac{R 2}{R 1} \times Vin .$$

However, when the conventional PGA circuit 10 is affected by an offset 16, an influence of the offset 16 may be defined as

$$\frac{R 2}{R 1} \times V O S .$$

FIG. 4 illustrates a PGA circuit 100 according to some embodiments of the inventive subject matter. The PGA circuit 100 may reduce or eliminate offset effects. In some embodiments, the PGA circuit 100 may be used for the PGA circuit 8 shown in FIG. 1.

The PGA circuit 100 may include a first input resistor 101, a second input resistor 102, a first feedback resistor 103, a second feedback resistor 104, a first reference resistor 105, a second reference resistor 106, and an OP-AMP 150. The first input resistor 101 is connected between the first input node IN1 and the first summing node T1. The second input resistor 102 is connected between the second input node IN2 and the second summing node T2. In some embodiments, the first and second input resistors 101 and 102 may have the same resistance value. A resistance value of each of the first and second input resistors 101 and 102 may be R1.

A positive input voltage VIP may include an offset 160 having a magnitude VOS. The positive input voltage VIP may be applied to the first input node IN1. A negative input voltage VIN may be applied to the second input node IN2. The input voltage Vin may be defined as a voltage difference between the positive input voltage VIP and the negative input voltage VIN.

The first feedback resistor 103 is connected between the first summing node T1 and a first output node OUT1. The second feedback resistor 104 is connected between the second summing node T2 and a second output node OUT2. In some embodiments, the first and second feedback resistors 103 and 104 may have the same resistance value. In some embodiments, the first and second feedback resistors 103 and 104 may be variable resistors. A resistance value of each of the first and second feedback resistors 103 and 104 may be R2.

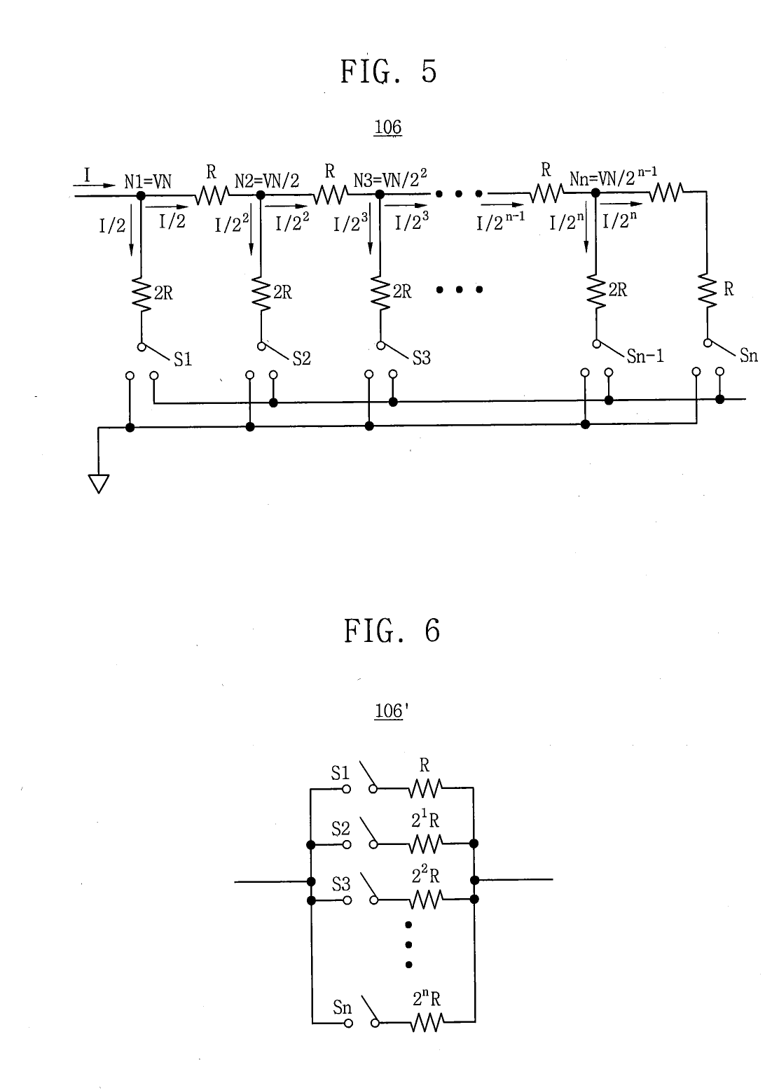

The first reference resistor 105 is connected between a third input node IN3 and the first summing node T1. The second reference resistor 106 is connected between a fourth input node IN4 and the second summing node T2. In some embodiments, the first and second reference resistors 105 and 106 may have the same resistance value. The first and second reference resistors 105 and 106 may be variable resistors. A resistance value of each of the first and second reference resistors 105 and 106 may be R3. A structure of each of the first and second reference resistors 105 and 106 will be described in detail with reference to FIGS. 5 to 7.

A positive reference voltage VP may be applied to the third input node IN3. A negative reference voltage VN may be applied to the fourth input node IN4. A reference voltage VREF is a difference between the positive reference voltage VP and the negative reference voltage VN.

An input of the OP-AMP 150 is connected to the first and second nodes N1 and N2. An output of the OP-AMP 150 is connected to the first and second output nodes OUT1 and OUT2.

A voltage of the first output node OUT1 is set as a positive output voltage OUTP. A voltage of the second output node OUT2 is set as a negative output voltage OUTN. An output voltage Vout is a difference between the positive output voltage OUTP and the negative output voltage OUTN.

An output voltage of the PGA circuit 100 may be given as:

$$Vout = \frac{R 2}{R 1} \times Vin + \frac{R 2}{R 1} \times V O S + \frac{R 2}{R 3} \times VREF \qquad ( Equation 2 )$$

When the PGA circuit 100 is affected by an offset 160, an influence of the offset 16 may be defined as

$$\frac{R 2}{R 1} \times V O S .$$

When the following equation is valid, the influence of the offset 160 may be removed:

$$\frac{R 2}{R 1} \times V O S = - \frac{R 2}{R 3} \times VREF \qquad ( Equation 3 )$$

Accordingly, the PGA circuit 100 according to some embodiments of the inventive subject matter may remove the influence of the offset 160. Equation 4 shows an ideal output voltage of the PGA circuit 100:

$$Vout = \frac{R 2}{R 1} \times Vin \qquad ( Equation 4 )$$

FIG. 5 is a circuit implementation for the first reference resistor shown in FIG. 4 using an R-2R ladder structure. Referring to FIGS. 1, 4 and 5, a positive reference voltage VP is applied to a third input node IN3. Current flows through a first reference resistor 105 to a first summing node T1. A negative reference voltage VN is applied to a fourth input node IN4. Current flows through a second reference resistor 106 to a second summing node T2.

The first and second reference resistors 105 and 106 may have the same resistance value and the same structure. In some embodiments, each of the first and second reference resistors 105 and 106 may include an R-2R ladder resistor structure. For example, the second reference resistor 106 may include the first to n^{th} switches Si to Sn for connecting a plurality of resistors to adjust a resistance value.

A DSP 9 may control the first to n^{th} switches. For example, the DSP 9 may activate at least one of the first to n^{th} switches. A resistance value of the second reference resistor 106 may be changed. In some embodiments, a resistance value of the second reference resistor 106 may change in an approximately linear manner.

The current decreases to half whenever passing through an R-2R resistor string one time. As each of the first to n^{th} switches is activated, the current flows to the second summing node T2 through a resistor of a value 2R. A voltage of the n^{th} node Nn in the second reference resistor 106 decrease to half whenever passing through an R-2R resistor string one time.

For example, a voltage of a first node N1 is twice greater than a voltage of a second node N2. Likewise, a voltage of a second node N2 is twice greater than a voltage of a third node N3.

The second reference resistor 106 may be approximately linearly increased or decreased using the above-described characteristic. Accordingly, the PGA 100 may approximately linearly remove an offset.

Reference voltage VREF may be calculated by Equation 5:

$$VREF = {\sum }_{k = 1}^{n - 1} \frac{1}{{2}^{k}} Sk + \frac{1}{{2}^{n - 1}} Sn \qquad ( Equation 5 )$$

Each of the first and second reference resistors 105 and 106 may include 3n−1 unit resistors having a resistance value R. For example, when n is 10 (i.e., a resolution of 10 bits), each of the first and second reference resistors 105 and 106 may be configured to 29 unit resistors having a resistance value R.

FIG. 6 is a circuit implementation of the second reference resistor shown in FIG. 4 using a parallel structure. A second reference resistor 106′ may include a parallel resistor structure. For example, the second reference resistor 106′ may include the first to n^{th} switches for connecting a plurality of resistors in order to change a resistance value.

A DSP 9 may control the first to n^{th} switches. For example, the DSP 9 may activate at least one of the first to n^{th} switches. A resistance value of the second reference resistor 106′ may be changed. In some embodiments, a resistance value of the second reference resistor 106′ may linearly increase.

In some embodiments, the second reference resistor 106′ may include 2″-1 unit resistors having a resistance value R. For example, when n is 10, the second reference resistor 106′ may be configured to 1023 unit resistors having a resistance value R.

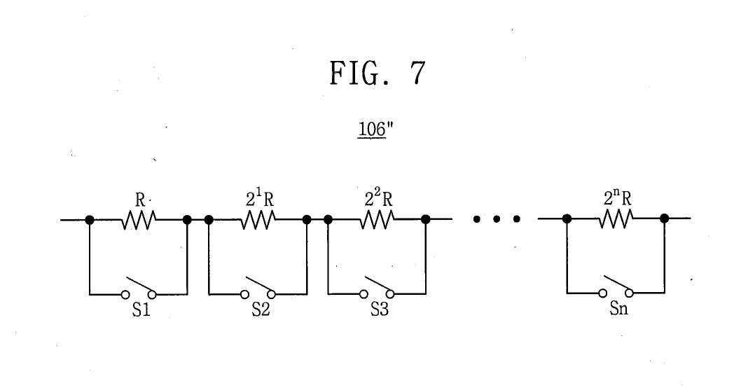

FIG. 7 is a circuit implementation for the second reference resistor shown in FIG. 4 using a serial structure. Referring to FIGS. 4 and 7, a second reference resistor 106″ may include a serial resistor structure. For example, the second reference resistor 106″ may include the first to n^{th} switches for connecting a plurality of resistors in order to change a resistance value.

A DSP 9 may control the first to n^{th} switches. For example, the DSP 9 may activate at least one of the first to n^{th} switches. A resistance value of the second reference resistor 106″ may be changed.

For example, a resistance value of the second reference resistor 106″ may be geometrically increased instead of a linear increase in response to an activation of the first to n^{th} switches.

In some embodiments, the second reference resistor 106″ may include 2ⁿ−1 unit resistors having a resistance value R. For example, when n is 10, the second reference resistor 106″ may be configured to 1023 unit resistors having a resistance value R. A resistance value R3 of the second reference resistor 106″ may be calculated by Equation 6:

$$R 3 = R \times {\sum }_{k = 1}^{n} {2}^{k} Sk \qquad ( Equation 6 )$$

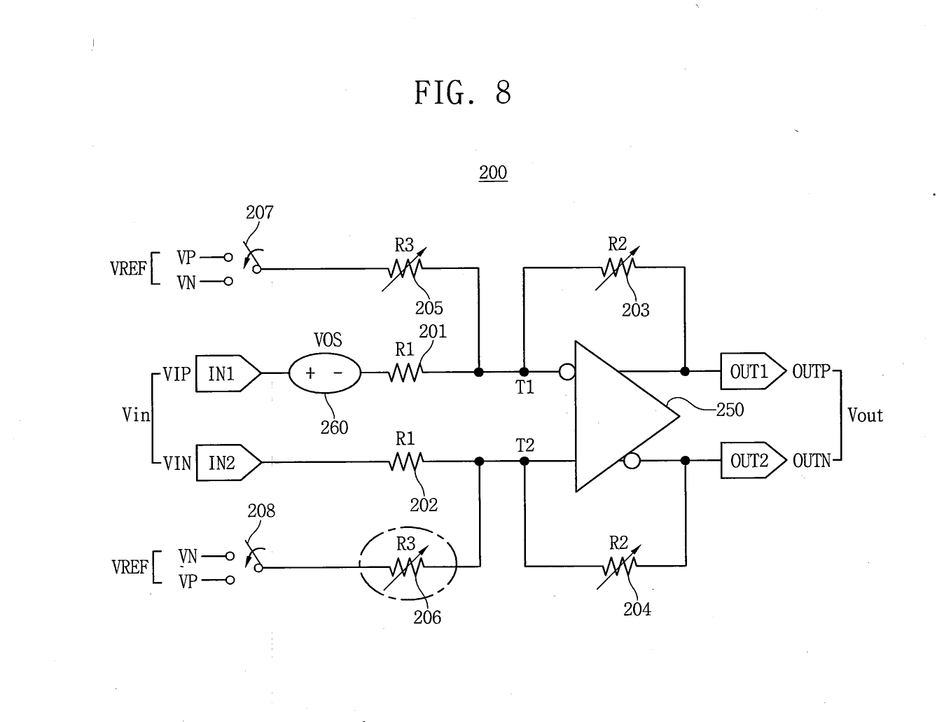

FIG. 8 is a circuit illustrating a PGA circuit according to further embodiments of the inventive subject matter. Referring to FIG. 8, a PGA circuit 200 may remove an offset. In some embodiments, the PGA circuit 200 may be used for the PGA circuit 8 shown in FIG. 1.

The PGA circuit 200 may include a first input resistor 201, a second input resistor 202, a first feedback resistor 203, a second feedback resistor 204, a first reference resistor 205, a second reference resistor 206, a first switch 207, a second switch 208, and an OP-AMP 250.

The first input resistor 201 is connected between a first input node IN1 and a first summing node T1. The second input resistor 202 is connected between a second input node IN2 and a second summing node T2. In some embodiments, the first and second input resistors 201 and 202 may have the same resistance value. A resistance value of each of the first and second input resistors 201 and 202 may be R1.

A positive input voltage VIP may include an offset 260. For example, a voltage of the offset 260 may be defined as VOS.

The positive input voltage VIP may be applied to the first input node IN1. A negative input voltage VIN may be applied to the second input node IN2. The input voltage Vin may be defined as a voltage difference between the positive input voltage VIP and the negative input voltage VIN.

The first feedback resistor 203 is connected between the first summing node T1 and a first output node OUT1. The second feedback resistor 204 is connected between the second summing node T2 and a second output node OUT2. In some embodiments, the first and second feedback resistors 203 and 204 may have the same resistance value. The first and second feedback resistors 203 and 204 may be variable resistors. A resistance value of each of the first and second feedback resistors 203 and 204 may be R2.

The first reference resistor 205 is connected between a first switch 207 and the first summing node T1. The second reference resistor 206 is connected between a second switch 208 and the second summing node T2. In some embodiments, the first and second reference resistors 205 and 206 may have the same resistance value. The first and second reference resistors 205 and 206 may be variable resistors. A resistance value of each of the first and second reference resistors 205 and 206 may be R3.

A positive reference voltage VP may be applied to the third input node IN3. A negative reference voltage VN may be applied to the fourth input node IN4. Reference voltage VREF is a difference between the positive reference voltage VP and the negative reference voltage VN.

The first switch 207 may select the positive reference voltage VP and the negative reference voltage VN. Likewise, the second switch 208 may select the positive reference voltage VP and the negative reference voltage VN. An input of the OP-AMP 250 is connected to the first and second nodes N1 and N2. An output of the OP-AMP 250 is connected to the first and second output nodes OUT1 and OUT2.

The PGA circuit 200 may apply the positive reference voltage VP and the negative reference voltage VN to the first switch 207 and the second switch 208 to set reference voltage for removing the offset 260. Further, the PGA circuit 200 may apply the negative reference voltage VN and the positive reference voltage VP to the first switch 207 and the second switch 208 in order to set reference voltage for removing the offset 260. Accordingly, the PGA circuit 200 may increase a removal range of the offset 260 twice greater than the PGA circuit 100 shown in FIG. 4.

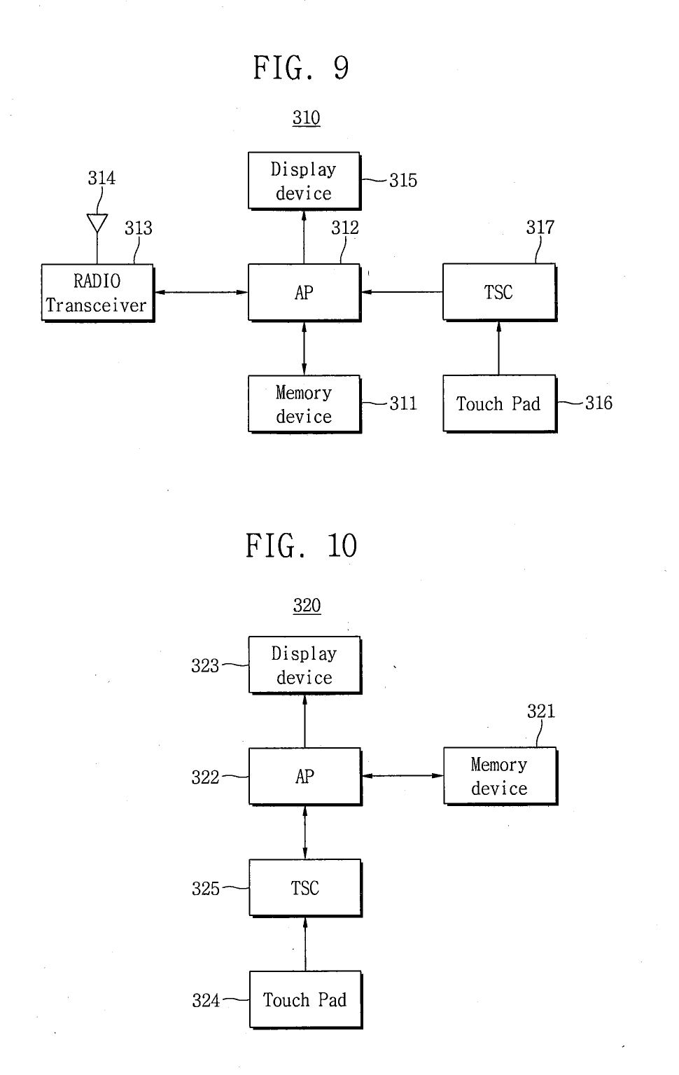

FIG. 9 is a block diagram illustrating a computer system including the touch sensor controller (TSC) shown in FIG. 1 in accordance with some embodiments of the inventive subject matter.

Referring to FIG. 9, a computer system 310 includes a memory device 311, an application processor (AP) 312 including a memory controller for controlling the memory device 311, a radio transceiver 313, an antenna 314, a display device 315, a touch pad 316, and a TSC 317.

The radio transceiver 313 transmits and receives a radio signal through the antenna 314. For example, the radio transceiver 313 converts the radio signal received through the antenna 314 into a signal which can be processed in the AP 312.

Accordingly, the AP 312 processes a signal output from the radio transceiver 313, and transmits the processed signal to the display device 315. Further, the radio transceiver 313 converts the signal output from the AP 312 into the radio signal, and transmits the converted radio signal to an external device through the antenna 314.

The touch pad 316 may receive a touch signal from a user. The touch pad 316 transforms the touch signal into a change amount of capacitance. The touch pad 316 transmits information about the change amount of capacitance to the TSC 317. The TSC 317 transforms the information about the change amount of capacitance into the coordinate information. The TSC 317 transmits the coordinate information to the AP 312.

In some embodiments, the TSC 317 may include the TSC 1 shown in FIG. 1.

FIG. 10 is a block diagram illustrating a computer system including the TSC shown in FIG. 1 in accordance with another embodiment of the inventive subject matter.

Referring to FIG. 10, a computer system 320 may be implemented as a personal computer (PC), a network server, a tablet PC, a netbook, an e-reader, a personal digital assistant (PDA), a portable multimedia player (PMP), an MP3 player, or an MP4 player.

The computer system 320 includes a memory device 321, an AP 322 including a memory controller for controlling a data processing operation of the memory device 321, a display device 323, a touch pad 324, and a TSC 325.

The touch pad 324 may receive a touch signal from a user. The touch pad 324 transforms the touch signal to a change amount of capacitance. The touch pad 324 transmits information about the change amount of capacitance to the TSC 325. The TSC 325 transforms the information about the change amount of capacitance to the coordinate information. The TSC 325 transmits the coordinate information to the AP 322.

The AP 322 may display data stored in the memory device 321 through the display device 323 according to data input through the touch pad 324.

In some embodiments, the TSC 325 may include the TSC 1 shown in FIG. 1.

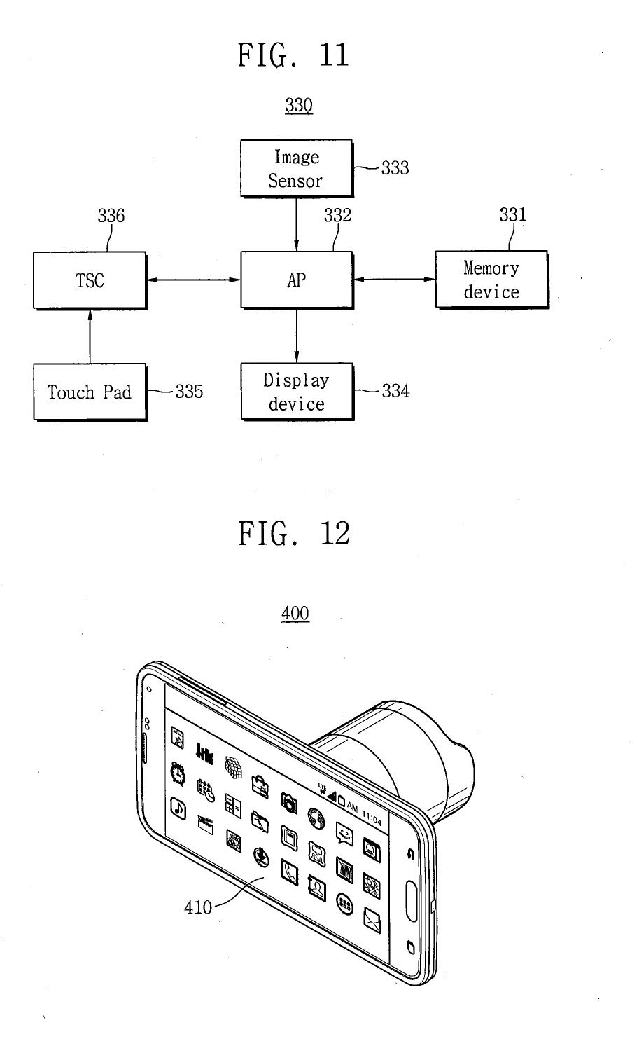

FIG. 11 is a block diagram illustrating a computer system including the TSC shown in FIG. 1 in accordance with still another embodiment of the inventive subject matter.

Referring to FIG. 11, a computer system 330 may be an image processing device, for example, a digital camera, or a mobile phone, a smart phone or a tablet PC on which the digital camera are installed.

The computer system 330 includes a memory device 331, an AP 332 including a memory controller for controlling a data processing operation, for example, a write operation or a read operation, of the memory device 331, an image sensor 333, a display device 334, a touch pad 335, and a TSC 336.

The image sensor 333 converts an optical image to digital signals, and the converted digital signals are transmitted to the AP 332. According to control of the AP 332, the converted digital signals are displayed through the display device 334, or stored in the memory device 331.

Further, the data stored in the memory device 331 is displayed through the display device 334 according to the control of the AP 332.

The touch pad 335 may receive a touch signal from a user. The touch pad 335 transforms the touch signal to a change amount of capacitance. The touch pad 335 transmits information about the change amount of capacitance to the TSC 336. The TSC 336 transforms the information about the change amount of capacitance to the coordinate information. The TSC 336 transmits the coordinate information to the AP 332.

In some embodiments, the TSC 336 may include the TSC 1 shown in FIG. 1.

FIG. 12 illustrates a digital camera device 400 including the TSC shown in FIG. 1.

Referring to FIG. 12, a digital camera device 400 operates with an Android™ operating system (OS). In some embodiments, the digital camera device 400 may include a Galaxy Camera™ or Galaxy Camera2™.

The digital camera device 400 may include a touch panel 410 to receive a touch input from a user, a TSC for controlling the touch panel 410, an image sensor for capturing an image or a moving image and an application processor for controlling the image sensor.

In some embodiments, the digital camera device 400 may include the TSC 1 shown in FIG. 1.

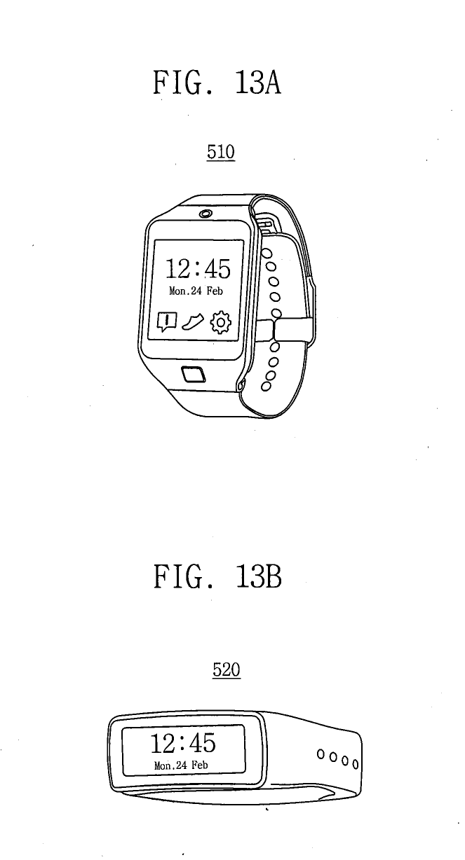

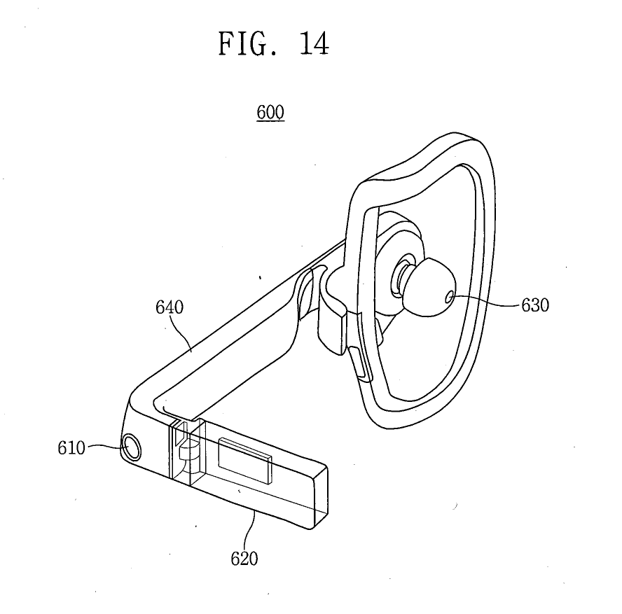

FIGS. 13A and 13B illustrate wearable devices including the TSC shown in FIG. 1.

Referring to FIGS. 13A and 13B, each of the first and second wearable devices 510 and 520 has a type of a wrist watch. Each of the first and second wearable devices 510 and 520 operates with an Android™ OS or TIZEN™ OS.

In some embodiments, the first wearable device 510 may include a Galaxy Gear2™ and the second wearable device 520 may include a Galaxy Gear Fit™.

Each of the first and second wearable device 510 and 520 may include a touch panel to receive a touch input from a user, a TSC for controlling the touch panel, an application processor which operates with an Android™ OS or TIZEN™ OS, an image sensor which captures an image or a moving image and a display device which displays the photographed image or a moving image.

In some embodiments, each of the first and second wearable devices 510 and 520 may include the TSC 1 shown in FIG. 1.

FIG. 14 illustrates a wearable device including the TSC shown in FIG. 1.

Referring to FIG. 14, the third wearable device 600 may be installed in an ear and provide sound and image information to a user. The third wearable device 600 operates with an Android™ OS or TIZEN™ OS.

In some embodiments, the third wearable device 600 may include a Galaxy Gear Blink™.

The third wearable device 600 may include an image sensor 610 which captures an image and a moving picture, a display device 620 which displays the photographed image, an earphone 630, a touch panel 640 for receiving a touch input from a user, a TSC for controlling the touch panel 640, and an AP (not shown) which controls the third wearable device 600.

In the embodiment, the third wearable device 600 may include the TSC 1 shown in FIG. 1.

The PGA circuit according to some embodiments of the inventive subject matter may be implemented with a small size compared to the conventional art.

The inventive subject matter may be applied to a touch sensor controller and a mobile device including the touch sensor controller

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive subject matter as defined in the claims. In the claims, means-plus-function clauses are intended to cover the structures described herein as performing the recited function, and not only structural equivalents but also equivalent structures.

What is claimed is:

1. A programmable gain amplifier (PGA) circuit comprising:
a first input resistor coupled between a first input node and a first summing node;
a second input resistor coupled between a second input node and a second summing node;
a first feedback resistor coupled between the first summing node and a first output node;
a second feedback resistor coupled between the second summing node and a second output node;
a first reference resistor coupled between a third input node and the first summing node;
a second reference resistor coupled between a fourth input node and the second summing node; and
an operational amplifier having an input coupled to the first and second summing nodes and an output coupled to the first and second output nodes, wherein at least one of the first and second reference resistors comprises an R-2R ladder circuit.

2. The PGA circuit according to claim 1, wherein the first and second input resistors have the same resistance value.

3. The PGA circuit according to claim 1, wherein a positive input voltage is applied to the first input node, a negative input voltage is applied to the second input node, and a difference between the positive input voltage and the negative input voltage is an input voltage.

4. The PGA circuit according to claim 1, wherein the first and second reference resistors comprise variable resistors.

5. The PGA circuit according to claim 4, wherein a positive reference voltage is applied to the third input node, a negative reference voltage is applied to the fourth input node, and a difference between the positive reference voltage and the negative reference voltage is a reference voltage.

6. The PGA circuit according to claim 5, wherein the positive input voltage includes an offset and the PGA circuit regulates a resistance value of each of the first and second reference resistors to remove the offset.

7. The PGA circuit according to claim 1, wherein the first and second feedback resistors have the same resistance value and the first and second feedback resistors comprise variable resistors.

8. The PGA circuit according to claim 1, wherein the first output node outputs a positive output voltage, the second output node outputs a negative output voltage, and a difference between the positive output voltage and the negative output voltage is an output voltage.

9. The PGA circuit of claim 1, further comprising:
a first switch configured to selectively couple the third input node to positive and negative voltage reference nodes; and
a second switch configured to selectively couple the fourth input node to the positive and negative reference voltage nodes.

10. A touch sensor controller comprising the PGA circuit of claim 1 and a demodulator having an output coupled to the first and second input nodes of the PGA circuit.

11. The touch sensor controller of claim 10, further comprising:
an analog-to-digital converter (ADC) having an input coupled to the first and second output nodes of the PGA circuit; and
a digital signal processor having an input coupled to an output of the ADC.

12. The touch sensor controller of claim 11, wherein the R-2R ladder circuit comprises a plurality of switches controlled by the DSP.

13. A programmable gain amplifier (PGA) circuit comprising:
a first input resistor coupled between a first input node and a first summing node;
a second input resistor coupled between a second input node and a second summing node;
a first feedback resistor coupled between the first summing node and a first output node;
a second feedback resistor coupled between the second summing node and a second output node;
a first variable reference resistor coupled between a third input node and the first summing node;
a second variable reference resistor coupled between a fourth input node and the second summing node; and
an operational amplifier having an input coupled to the first and second summing nodes and an output coupled to the first and second output nodes.

14. The PGA circuit of claim 13, wherein at least one of the first and second reference resistors comprises an R-2R ladder circuit.

15. The PGA circuit of claim 14, wherein the R-2R ladder circuit comprises a plurality of switches operative to vary a resistance of the R-2R ladder circuit responsive to control signals applied to the switches.

16. The PGA circuit of claim 13, further comprising:
a first switch configured to selectively couple the third input node to positive and negative voltage reference nodes; and
a second switch configured to selectively couple the fourth input node to the positive and negative reference voltage nodes.

17. A touch sensor controller comprising:
a demodulator configured to be coupled to a touch sensor and to generate a DC output voltage responsive to an input to the touch sensor;
a programmable gain amplifier (PGA) circuit comprising:
first and second input nodes coupled to an output of the demodulator;
first and second output nodes;
a first input resistor coupled between the first input node and a first summing node;
a second input resistor coupled between the second input node and a second summing node;
a first feedback resistor coupled between the first summing node and the first output node;
a second feedback resistor coupled between the second summing node and the second output node;
a first variable reference resistor coupled between a third input node and the first summing node;
a second variable reference resistor coupled between a fourth input node and the second summing node; and
an operational amplifier having an input coupled to the first and second summing nodes and an output couple to the first and second output nodes; and
an analog-to-digital converter (ADC) having an input coupled to the first and second output nodes of the PGA circuit.

18. The touch sensor controller of claim 13, wherein at least one of the first and second reference resistors comprises an R-2R ladder circuit.

19. The touch sensor controller of claim 18, wherein the R-2R ladder circuit comprises a plurality of switches operative to vary a resistance of the R-2R ladder circuit responsive to control signals applied to the switches.

20. The touch sensor controller of claim 17, wherein the PGA circuit further comprises:
a first switch configured to selectively couple the third input node to positive and negative voltage reference nodes; and
a second switch configured to selectively couple the fourth input node to the positive and negative reference voltage nodes.
